(19) United States
(12) Patent Application Publication
(10) Pub. No.: US 2015/0207011 A1
(43) Pub. Date: Jul. 23, 2015

(54) MULTI-JUNCTION PHOTOVOLTAIC CELLS AND METHODS FOR FORMING THE SAME

(71) Applicant: URIEL SOLAR, INC., Westlake Village, CA (US)

(72) Inventors: James David Garnett, Simi Valley, CA (US); Peter Dingus, Mission Viejo, CA (US)

(21) Appl. No.: 14/576,085

(22) Filed: Dec. 18, 2014

Related U.S. Application Data
(60) Provisional application No. 61/919,452, filed on Dec. 20, 2013.

(51) Int. Cl. H01L 31/078; H01L 31/0368

(52) U.S. Cl. CPC H01L 31/078; H01L 31/0368

(57) ABSTRACT

The present disclosure provides thin film solar cell structures that can achieve dramatically improved power conversion efficiencies in relation to other thin film solar cell structures. The application of tandem solar cells composed of poly-crystalline Group II-VI (e.g., CdTe-based alloy) solar cells under low temperature deposition can achieve practical efficiencies above 25% in a low cost, high through-put, large area production environment. A poly-crystalline Group II-VI (e.g., CdTe-based alloy) solar cell can be deposited in tandem with a crystalline or multi-crystalline silicon p-type substrate with embedded n-type emitter on the deposition side of the substrate. This low temperature poly-crystalline/crystalline approach can allow for the development of a substantially efficient tandem solar cell produced in a relatively low cost, high through-put, large area production environment.

### CROSS REFERENCE

This patent application claims priority to U.S. Provisional Patent Application Ser. No. 61/919,452, filed Dec. 20, 2013, which is entirely incorporated herein by reference.

### BACKGROUND

A photovoltaic cell is able to absorb radiant light energy and convert it directly into electrical energy. Some photovoltaic (“PV”) cells are employed as a measure of the ambient light in non-imaging applications or (in an array format) as imaging sensors in cameras to obtain an electrical signal for each portion of the image. Other photovoltaic cells are used to generate electrical power. Photovoltaic cells can be used to power electrical equipment for which it has proven difficult or inconvenient to provide a source of continuous electrical energy.

An individual photovoltaic cell has a distinct spectrum of light to which it is responsive. The particular spectrum of light to which a photovoltaic cell is sensitive is primarily a function of the material forming the cell. Photovoltaic cells that are sensitive to light energy emitted by the sun and are used to convert sunlight into electrical energy can be referred to as solar cells.

Individually, any given photovoltaic cell is capable of generating only a relatively small amount of power. Consequently, for most power generation applications, multiple photovoltaic cells are connected together in series, or a combination of series and parallel, into a single unit, which can be referred to as an array. When a photovoltaic cell array, such as a solar cell array (also known as a solar module), produces electricity, the electricity can be directed to various locations, such as, e.g., a home or business, or a power grid for distribution.

The theoretical maximum power conversion efficiency for a single junction solar cell is approximately 30%. Solar (or photovoltaic) cells with multiple junctions (i.e., multi-junction solar cells) may permit higher efficiencies. Such devices capture different portions of the available solar light. The most common arrangement is multi-junction solar cells in series, connected by the use of quantum tunnel junctions, with the band-gaps of each solar cell arranged from highest band-gap to lowest band-gap with light incident on the highest band-gap side of the multi-junction.

There are PV cells available in the art that achieve power conversion efficiencies above 30%, but these are costly to produce and are built entirely as crystalline structures with tremendous efforts to lattice match the different band-gap cells in order to prevent crystal threading dislocations and recombination sites that may act as traps and degrade the performance of the multi-junction cell. Accordingly, there is a need in the art for improved multi-junction PV cells and methods for producing the same at lower production costs and high power conversion efficiency.

Research has focused on the Group III-V semiconductors, such as InGaAs, InGaP, AlInGaAs, AlInGaP, and InGaN, to produce the world's best multi-junction crystalline solar cells. But the material costs of these III-V materials and the Ge substrate they are grown on are much higher than the costs of Group II-VI materials (e.g., CdTe-based alloy materials) grown on alternative substrate materials.

One reason multi-junction cells using Group II-VI materials have not been investigated much is the absence of suitably lattice-matched substrates. However, in the last couple of decades dislocations have been shown to have a much smaller effect on CdTe-based alloys than in Group III-V alloys, so the lattice-matching requirement is greatly relaxed for Group II-VI multi-layer crystalline solar cell structures.

U.S. Pat. Nos. 5,477,809 and 5,759,266 to Kawano, which are entirely incorporated herein by reference, disclose a method to allow high quality crystalline CdTe deposition on mono-crystalline silicon substrates to provide a path to larger area, state-of-the art II-VI semiconductor infrared detectors. Commercially available mono-crystalline silicon or GaAs substrates are much larger and cheaper than conventional lattice matched Cd(Zn)Te substrates used in current infrared detector arrays. The disclosure discusses the techniques to minimize the deleterious effects of lattice mismatched II-VI CdTe or ZnTe on the silicon or GaAs substrate.

U.S. patent application Ser. No. 12/261,827 discloses an approach to make high efficiency II-VI multi-junction crystalline solar cells for CPV or space applications grown on silicon, offering a significant cost advantage over the much more costly III-V multi-junction crystalline solar cells typically grown on Ge or GaAs. This patent further discloses an II-VI crystalline (monolithic) solar cell grown on II-VI or IV substrate. This crystal growth, by its very nature, will be a relatively slow deposition rate unsuitable for lowest cost, high through-put production, although usable for higher-cost space applications or concentrator PV where a single, more expensive, multi-junction solar cell can be utilized for a very large solar collection area. With the exception of crystalline or multi-crystalline silicon solar cells, a II-VI or III-V crystalline solar cell strategy is not suitable for commercial markets due to its low through-put and relatively high cost per Watt. Silicon is currently the only competitive crystalline solar cell to thin film poly-crystalline solar cells due to the very low cost of silicon feedstock. But silicon has fixed band-gap energy and cannot be tuned, unlike copper indium gallium selenide (CIGS) and CdTe-based alloys which can change the composition of constituents to obtain different energy band-gaps.

### SUMMARY

Recognized herein is the need for photovoltaic (PV) devices that are capable of capturing a large fraction of incident solar light with larger open circuit voltage as compared to other PV devices currently available. Also recognized herein is the need for commercially viable (e.g., scalable, low cost) methods for forming such devices.

The present disclosure provides photovoltaic devices, system and methods that utilize poly-crystalline (or multi-crystalline) Group II-VI dual junctions grown on glass or a poly-crystalline Group II-VI single junction grown on a relatively low cost crystalline (e.g., single crystal) or multi-crystalline silicon p-type (or n-type) substrate with an n-type (or p-type) embedded emitter. Through the use of an appropriate, amorphous or poly-crystalline tunnel junction deposited onto the crystalline substrate, the subsequent Group II-VI growth may proceed as poly-crystalline and hence the threading dislocations may be greatly ameliorated due to the presence of grain boundaries to take up the dislocations generated from the lattice mismatch. In addition, the more relaxed growth tolerances required by poly-crystalline growth compared with crystalline growth can allow for high deposition rates and low temperature growth.

Group II-VI poly-crystalline structures of the present disclosure can be deposited at high deposition rates and relatively low temperatures, allowing low cost, large panel production. It is the unique poly-crystalline Group II-VI deposition that affords low cost production as well as the ability to minimize threading dislocations due to the lattice mismatch between the crystalline silicon substrate and the poly-crystalline CdTe-based alloy, in the one case, or dual poly-crystalline CdTe-based alloys of different band-gaps grown on inexpensive substrates, e.g., glass or metal foil, in the other case.

Deposition of a poly-crystalline II-VI CdTe-based alloy onto a crystalline silicon substrate with built-in p-n junction is possible by a suitable tunnel junction connection. The large lattice mismatch is taken up in the grain boundaries and practical power conversion efficiencies in excess of 20%, 25%, 26%, 27%, 28%, 29%, or 30% are obtainable. This entire process can be implemented in a low cost production method, with material deposition at low temperature and high deposition rate on a superstrate or substrate by vacuum effusion cells, including cells that can crack molecular species through filament or plasma heating. These material sources may be classical effusion cells or distributed arrays, as in linear effusion sources. These sources can be operated in a spectrum of vacuum modes including, but not limited to, beam mode to gas mode. This deposition method is referred to herein as Molecular Effusion Deposition (MED). Other example vapor deposition methods that may be used to deposit material layers of the present disclosure include physical vapor deposition, chemical vapor deposition and atomic layer deposition.

Photovoltaic devices of the present disclosure, such as Group II-VI photovoltaic devices, can be formed using various deposition techniques, such as vapor phase deposition techniques. In an example, molecular beam epitaxy is employed to form Group II-VI photovoltaic devices provided herein. As an alternative, a Group II-VI photovoltaic device can be formed using physical vapor deposition (PVD), chemical vapor deposition (CVD), atomic layer deposition (ALD), or plasma-enhanced variants thereof.

Deposition of dual poly-crystalline Group II-VI (e.g., CdTe-based alloys) with suitably tuned energy band-gaps onto a glass substrate can be produced with practical power conversion efficiencies in excess of 20% or 25%. This entire process can be implemented in a relatively low cost production method.

An aspect of the invention provides a process for forming high performance, multi (e.g., two) junction photovoltaic devices, comprising high deposition rate poly-crystalline growth using molecular effusion deposition (MED). In an embodiment, the process further provides the capability to do the following: in situ superstrate (or substrate) temperature control; in situ doping of the p-n junction; in situ, high doping; in situ thermal anneal; in situ grain boundary passivation by overpressure of suitable source constituents; compositional grading during growth by flux level control of suitable source constituents; high precision control over layer thicknesses; and high precision control over deposition growth rates. In an embodiment, the process temperature ranges from about 150° C. to 450° C., or from about 200° C. to 400° C., or from about 250° C. to 350° C. can be accommodated.

In an embodiment, doping of p-n junctions can range from 1×10¹⁴ cm⁻³ to 1×10¹⁷ cm⁻³ for both p-type and n-type dopants. In another embodiment, high doping can range from 1×10¹⁸ cm⁻³ to 1×10²⁰ cm⁻³ for both p-type and n-type dopants.

In an embodiment, for the process a thermal anneal range of 50° C. to 200° C., above the deposition temperature can be accommodated. Overpressures of suitable source constituents of about 5% to 100% above nominal base II-VI growth pressure can be accommodated. In addition, flux levels of source constituents can be varied stepwise or in a finer fashion from no flux to substantially high fluxes so as to provide the necessary growth rates. In an embodiment, for the process, layer thicknesses can be controlled at the ˜10 nm level of growth or better.

In an embodiment, growth rates can be varied stepwise or finer from about 1 micron per hour to 36 microns per hour, or 6 microns per hour to 12 microns per hour. In another embodiment, growth rates can be varied stepwise or finer from about 18 microns per hour to 30 microns per hour or faster.

Another aspect of the invention provides dual poly-crystalline p-n junction photovoltaic cell (also “photovoltaic cell” herein) structures having at least two layers of compound semiconductor materials, comprising SbₘTeₙ, ZnTe, CdTe, Cd₍₁₋ₓ₎ZnₓTe, MgTe, Mg₍₁₋ₓ₎ZnₓTe, Cd₍₁₋ₓ₎MgₓTe, CdSe, ZnSe, CdSeₓTe₍₁₋ₓ₎, Cd₍₁₋ₓ₎ZnₓSe_{y}Te_{(1-y)}, ZnS, or Cd₍₁₋ₓ₎ZnₓS where x and/or y can be tuned between 0 and 1 to optimize the relative band-gaps between the solar cells.

In an alternative embodiment, a single poly-crystalline photovoltaic cell having at least two layers of compound semiconductor materials, comprising SbₘTeₙ, ZnTe, CdTe, Cd₍₁₋ₓ₎ZnₓTe, MgTe, Mg₍₁₋ₓ₎ZnₓTe, Cd₍₁₋ₓ₎MgₓTe, CdSe, ZnSe, CdSeₓTe₍₁₋ₓ₎, Cd₍₁₋ₓ₎ZnₓSe_{y}Te_{(1-y)}, ZnS or Cd₍₁₋ₓ₎ZnₓS is deposited onto a p-type (n-type) silicon substrate with an n-p (p-n) junction on the side adjacent to the poly-crystalline II-VI cell and where x and/or y can be tuned between 0 and 1 to optimize the relative band-gaps between the poly-crystalline II-VI cell and the silicon cell.

The dual poly-crystalline solar cell structures can be grown on a superstrate with a transparent conductive oxide (“TCO”) and optional high resistance transparent conductor (HRT), or a substrate with a metal or metal/low band-gap semiconductor contact. Successive semiconductor layers deposited to provide, in sequence, a thin, higher doped first layer for contact to the TCO (TCO/HRT) or metal (metal/low band-gap semiconductor), which may be integral to the second layer as a compositional grading, and which may also serve as a window layer and/or minority carrier reflection layer, an n-p (p-n) junction second and third layers, a higher doped fourth layer, which may be integral to the third layer as a compositional grading, a high-doped p+/n+(n+/p+) tunnel junction fifth and sixth layers, a higher doped seventh layer, an n-p (p-n) junction eighth and ninth layers, and a higher doped tenth contact layer, which may be integral to the ninth layer as a compositional grading, to a TCO or metal, and which may serve as a window layer or minority carrier reflection layer.

In an embodiment the dual poly-crystalline higher band-gap energy n-p (p-n) junction consists of one or more of Cd₍₁₋ₓ₎ZnₓTe and CdSe_{y}Te_{(1-y)} with “x” between about 0.6 and 1.0 and “y” between about 0.85 and 1.0; the lower band-gap energy n-p (p-n) junction consists of one or more of Cd₍₁₋ₓ₎ZnₓTe and CdSe_{y}Te_{(1-y)} with “x” between 0 and about 0.2 and “y” between 0 and about 0.40, or between about 0.65 and about 0.8.

In some embodiments, where the heterojunction interfaces consist of Cd₍₁₋ₓ₎ZnₓTe and CdSe_{y}Te_{(1-y)} the compositions ‘x,’ ‘y’ are chosen to closely lattice-match the dissimilar materials while providing an optimal band-gap for light absorption and proper doping.

In some embodiments, the n-type layer of a cell is compositionally graded away from the junction to ZnSe, CdSe, CdTe, or MgTe and the p-type layer is compositionally graded away from the junction to ZnTe or MgTe.

In some embodiments, the lower band-gap n-p junction comprises Cd₍₁₋ₓ₎ZnₓTe for the p-type layer and CdSe_{y}Te_{(1-y)} or Cd₍₁₋ₓ₎ZnₓTe for the n-type layer with ‘x’≦0.10 and 0.2≦‘y’≦0.3, or 0.75≦‘y’≦0.8, and the higher band-gap energy n-p junction comprises Cd₍₁₋ₓ₎ZnₓTe for the p-type layer and CdSe_{y}Te_{(1-y)} or Cd₍₁₋ₓ₎ZnₓTe for the n-type layer with 0.70≦‘x’≦0.85 and 0.95≦‘y’≦1.

The single junction poly-crystalline solar cell structure is grown on a silicon substrate doped p-type (n-type) with an embedded n-type (p-type) emitter on the poly-crystalline deposition side. Successive semiconductor layers deposited to provide, in sequence, a high-doped n+/p+(p+/n+) tunnel junction first and second layers that act as window layers for light into the silicon cell, a thin, higher doped third layer for contact to the tunnel junction, which may be integral to the fourth layer as a compositional grading, an p-n (n-p) junction fourth and fifth layers, a higher doped six layer, which may be integral to the fifth layer as a compositional grading, that makes contact to a TCO (TCO/HRT).

In some embodiments, the poly-crystalline higher band-gap energy p-n junction comprises Cd₍₁₋ₓ₎ZnₓTe for the p-type layer and Cd₍₁₋ₓ₎ZnₓTe, CdSe_{y}Te_{(1-y)}, or ZnSe for the n-type layer with 0.35≦‘x’≦0.45 and 0.90≦‘y’≦1.0, or ‘x’=1 and ‘y’=1.

In some embodiments, the n+/p+ tunnel junction is an n+ TCO, such as ITO, or n+ ZnSe and p+ ZnTe.

In some embodiments, the n+/p+ (p+/n+) tunnel junction is an n+ (p+) silicon layer embedded in the n-type (p-type) silicon emitter, and p+ ZnTe (n+ TCO or n+ ZnSe or n+ CdSe).

In an embodiment, a MED technique, or similar medium to high vacuum, free-streaming flux of elements or reactive molecules can be operated in a mode of high deposition rate, 18-30 microns/hour, to produce II-VI poly-crystalline material structure with a total thickness between about 1 micrometers (“microns”) and 4 microns deposited onto an optically transparent superstrate, e.g., a piece of glass (the “superstrate”), or silicon crystal or multi-crystalline substrate, or poly-crystalline or amorphous silicon or non-transparent metal (the “substrate”), at a deposition temperature between about 200° C. and 400° C. with superstrate/substrate area from between 150 mm×150 mm to 2000 mm×2000 mm. In another embodiment, a metalorganic chemical vapor deposition (MOCVD) or plasma enhanced physical vapor deposition (PEPVD) or similar technique can be used to provide the necessary process capabilities.

An aspect of the present disclosure provides a photovoltaic device, comprising (a) a glass substrate; (b) a first n-type emitter adjacent to the glass substrate, the first n-type emitter comprising cadmium (Cd), tellurium (Te) and one or more of selenium (Se) and zinc (Zn); (c) a first p-type absorber adjacent to the first n-type emitter, the first p-type absorber comprising two or more of Cd, Zn and Te; (d) a second n-type emitter adjacent to the first p-type absorber, the second n-type emitter comprising Cd, Te and one or more of Se and Zn at a composition that is different than a composition of the first n-type emitter; and (e) a second p-type absorber adjacent to the second n-type emitter, the second p-type absorber comprising Cd, Zn and Te at a composition that is different than a composition of the first p-type absorber. In an embodiment, a concentration of Se or Zn in the first n-type emitter is higher than a respective concentration of Se or Zn in the second n-type emitter. In another embodiment, a concentration of Zn in the first p-type absorber is higher than a concentration of Zn in the second p-type absorber.

In an embodiment, the photovoltaic device further comprises a p-n tunnel junction between the first p-type absorber and the second n-type emitter. In another embodiment, the p-n tunnel junction comprises a p-type layer adjacent to an n-type layer, wherein the p-type layer comprises Te and Zn, and wherein the n-type layer comprises (i) Zn and Se or (ii) indium tin oxide.

In an embodiment, the first and/or second n-type emitter is compositionally graded in (i) Se and Te and/or (ii) Cd and Zn. In another embodiment, the first and/or second p-type absorber is compositionally graded in Cd and Zn.

In an embodiment, the photovoltaic device further comprises a transparent conductive oxide (TCO) layer between the glass substrate and the first n-type emitter. In another embodiment, transparent conductive oxide layer comprises indium tin oxide. In another embodiment, the photovoltaic device further comprises a higher resistive layer between the TCO and the first n-type emitter. In another embodiment, the high resistive layer has a resistivity from about 10² to 10⁴ times a resistivity of the TCO. In another embodiment, the high resistive layer comprises tin (Sn) and oxygen (O).

In an embodiment, the photovoltaic device further comprises a metal contact adjacent to the second p-type absorber. In another embodiment, the metal contact comprises molybdenum. In another embodiment, the photovoltaic device further comprises a p-type layer comprising Zn and Te between the second p-type absorber and the metal contact. In another embodiment, the photovoltaic device further comprises a layer comprising antimony (Sb) and Te between (i) the second p-type absorber and the metal contact or (ii) the p-type layer comprising Zn and Te layer and the metal contact.

Another aspect of the present disclosure provides a photovoltaic device, comprising (a) a glass substrate; (b) a first n-type emitter adjacent to the glass substrate, the first n-type emitter comprising two or more of cadmium (Cd), tellurium (Te), selenium (Se) and zinc (Zn); (c) a first p-type absorber adjacent to the n-type emitter, the first p-type absorber comprising Cd, Zn and Te; (d) a second n-type emitter adjacent to the first p-type absorber, the second n-type emitter comprising silicon; and (e) a second p-type absorber adjacent to the second n-type emitter, the second p-type absorber comprising silicon.

In an embodiment, the second n-type emitter comprises crystalline or multi-crystalline silicon. In another embodiment, the second p-type absorber comprises crystalline or multi-crystalline silicon.

In an embodiment, the photovoltaic device further comprises a p-n tunnel junction between the first p-type absorber and the second n-type emitter. In another embodiment, the p-n tunnel junction comprises a p-type layer adjacent to an n-type layer, wherein the p-type layer comprises Te and Zn, and wherein the n-type layer comprises (i) Zn and Se or (ii) indium tin oxide.

In another embodiment, the first n-type emitter comprises Cd, Zn and Te. In another embodiment, the first n-type emitter is compositionally graded in Cd and Zn. In another embodiment, the first n-type emitter comprises two or more of Cd, Te and Se. In another embodiment, the first n-type emitter comprises Cd and Se.

In an embodiment, the first p-type absorber is compositionally graded in Cd and Zn. In another embodiment, the photovoltaic device further comprises a transparent conductive oxide layer between the glass substrate and the first n-type emitter. In another embodiment, the transparent conductive oxide layer comprises indium tin oxide. In another embodiment, the photovoltaic device further comprises a high resistive layer comprising tin (Sn) and oxygen (O) between the TCO and the first n-type emitter.

Another aspect of the present disclosure provides a photovoltaic device, comprising (a) a glass substrate; (b) a first p-type emitter adjacent to the glass substrate, the first p-type emitter comprising two or more of Cd, Zn and Te; (c) a first n-type absorber adjacent to the first p-type emitter, the first n-type absorber comprising cadmium (Cd), tellurium (Te) and one or more of selenium (Se) and zinc (Zn); (d) a second p-type emitter adjacent to the first n-type absorber, the second p-type emitter comprising Cd, Zn and Te at a composition that is different than a composition of the first p-type emitter; and (e) a second n-type absorber adjacent to the second p-type emitter, the second n-type absorber comprising Cd, Te and one or more of Se and Zn at a composition that is different than a composition of the first n-type absorber.

In an embodiment, a concentration of Se or Zn in the first n-type absorber is higher than a respective concentration of Se or Zn in the second n-type absorber. In another embodiment, a concentration of Zn in the first p-type emitter is higher than a concentration of Zn in the second p-type emitter.

In an embodiment, the photovoltaic device further comprises an n-p tunnel junction between the first n-type absorber and the second p-type emitter. In another embodiment, the first and/or second n-type absorber is compositionally graded in (i) Se and Te and/or (ii) Cd and Zn. In another embodiment, the first and/or second p-type emitter is compositionally graded in Cd and Zn.

In an embodiment, the photovoltaic device further comprises a transparent conductive oxide (TCO) layer between the glass substrate and the first p-type emitter. In another embodiment, the transparent conductive oxide layer comprises indium tin oxide.

In an embodiment, the photovoltaic device further comprises a higher resistive layer between the TCO and the first p-type emitter. In another embodiment, the high resistive layer has a resistivity from about 10² to 10⁴ times a resistivity of the TCO. In another embodiment, the high resistive layer comprises tin (Sn) and oxygen (O).

In an embodiment, the photovoltaic device further comprises a metal contact adjacent to the second n-type absorber. In another embodiment, the metal contact comprises molybdenum.

Another aspect of the present disclosure provides a photovoltaic device, comprising (a) a glass substrate; (b) a first p-type emitter adjacent to the glass substrate, the first p-type emitter comprising Cd, Zn and Te; (c) a first n-type absorber adjacent to the first p-type emitter, the first n-type absorber comprising two or more of cadmium (Cd), tellurium (Te), selenium (Se) and zinc (Zn); (d) a second p-type emitter adjacent to the first n-type absorber, the second p-type emitter comprising silicon; and (e) a second n-type absorber adjacent to the second p-type emitter, the second n-type absorber comprising silicon.

In an embodiment, the second p-type emitter comprises crystalline or multi-crystalline silicon. In another embodiment, the second n-type absorber comprises crystalline or multi-crystalline silicon. In another embodiment, the photovoltaic device further comprises an n-p tunnel junction between the first n-type absorber and the second p-type emitter. In another embodiment, the first n-type absorber comprises Cd, Zn and Te. In another embodiment, the first n-type absorber is compositionally graded in Cd and Zn. In another embodiment, the first n-type absorber comprises two or more of Cd, Te and Se.

In an embodiment, the first n-type absorber comprises Cd and Se. In another embodiment, the first p-type emitter is compositionally graded in Cd and Zn.

In an embodiment, the photovoltaic device further comprises a transparent conductive oxide layer between the glass substrate and the first p-type emitter. In another embodiment, the transparent conductive oxide layer comprises indium tin oxide.

In an embodiment, the photovoltaic device further comprises a high resistive layer comprising tin (Sn) and oxygen (O) between the TCO and the first p-type emitter. In another embodiment, the n-p tunnel junction comprises an n-type layer adjacent to a p-type layer, wherein the n-type layer comprises (i) Zn and Se or (ii) indium tin oxide, and wherein the p-type layer comprises Te and Zn.

Another aspect of the present disclosure provides methods for forming photovoltaic devices provided above and elsewhere herein, comprising sequentially forming various layers (e.g., emitter and absorber) to provide a device structure as set forth herein.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the invention will be obtained by reference to the following detailed description that sets forth illustrative embodiments, in which the principles of the invention are utilized, and the accompanying drawings of which:

FIG. 1 shows the top cell of a dual poly-crystalline solar cell structure, in accordance with an embodiment of the invention;

FIG. 2 shows the bottom cell of a dual poly-crystalline solar cell structure, in accordance with an embodiment of the invention;

FIG. 3 shows a single poly-crystalline solar cell structure on a crystalline or multi-crystalline or poly-crystalline silicon p+ substrate with embedded n+ emitter on the deposition side of the substrate, in accordance with an embodiment of the invention; and

FIG. 4 shows a table of optimized top and bottom cell zinc content for the CdZnTe embodiment of the invention.

### DETAILED DESCRIPTION

While various embodiments of the invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention.

The term “n-type,” as used herein, generally refers to a material or layer that is chemically doped n-type. A Group IV semiconductor can be doped n-type by the incorporation of, for example, Group V nitrogen or phosphorous.

The term “p-type,” as used herein, generally refers to a material or layer that is chemically doped p-type. A Group IV semiconductor can be doped p-type by the incorporation of, for example, Group III boron or aluminum.

The term substrate, as used herein, generally refers to a material upon which one or more layers or a device is formed. A substrate (or superstrate) can be transparent to at least a portion of incident light. A substrate can be formed of a metal, semiconductor, insulator, or a combination thereof.

The term “emitter,” as used herein, generally refers to the p-n junction layer of a photovoltaic device that light first enters. The emitter layer may be thinner and higher doped than the absorber layer.

The term “absorber,” as used herein, generally refers to the p-n junction layer of a photovoltaic device that light enters after passing through the emitter layer. The absorber layer may be thicker and lower doped than the emitter layer.

In current thin film photovoltaic cells, such as CdTe or CIGS, a CdS “window” layer is used because it is an intrinsically n-type material. Because current process technologies used in production do not provide the capability of doping photovoltaic structures in situ (i.e., real time in the deposition chamber), those of skill in the art use a material with high intrinsic n-type doping, such as CdS, to define the n-type layer of the p-n junction. But there are limitations associated with using CdS. For example, CdS (at a CdS/CdTe interface) can reduce useable electrical current by absorbing incoming photons, which in turn create charge carriers that contribute very little, if at all, to the electrical current of the diode. In some cases, this problem is due to a combination of a band gap barrier between the CdS/CdTe layers (band-gap alignment problem) or large recombination rates at a low quality CdS/CdTe interface layer. In overcoming these limitations, one approach is to reduce the thickness of the CdS light absorbing layer as much as possible to limit the amount of incoming light that is absorbed in this “dead layer.” But below about 100 nanometers, the CdS layer can develop pinholes and non-uniformities (primarily from the intermixing between CdS and CdTe) that degrade device performance.

In various embodiments, methods for forming cadmium telluride (CdTe) based alloy thin film solar cell structures are provided. Methods of embodiments provide for forming high quality CdTe based alloy thin films at high deposition rates. CdTe based alloy thin film structures of preferable embodiments can provide for high power conversion efficiency in solar cell (also “photovoltaic cell” or “photovoltaic” herein) devices.

Methods of preferable embodiments are suitable for forming solar panels using molecular effusion deposition (MED) at high deposition rates, relatively low temperatures and poly-crystalline deposition modes, while providing the advantages of in situ doping, composition and uniformity control. Methods of various embodiments enable formation of solar cell structures having uniform compositions, longer lifetime, and larger grain sizes, which provide for enhanced device performance.

In preferable embodiments, doping of structural layers of solar cell devices with shallow donors and acceptors is performed in situ, i.e., during deposition of solar cell device structural layers. Suitable dopants are elements from Group III (e.g., Al, Ga, In), Group V (e.g., N, P, As, Sb) and Group VII (e.g., Cl, I). Conventional chemical vapor deposition techniques suffer from low solubility issues with the shallow level donors/acceptors or difficulty with complete ionization for deeper level donors/acceptors. By doping the structure in situ at low temperatures the solubility issues are reduced and hence the technique allows the use of the shallow donor/acceptors to provide high doping levels, necessary to build improved performance solar cells. This advantageously reduces, if not eliminates, interstitial or intrinsic (defect) dopants by providing substitutional dopants. Substitutional dopants can provide for more stable solar cell devices because of their much lower diffusion compared to interstitial dopants. MED methods of the present disclosure can advantageously provide for forming high quality thin film solar cell devices with higher power efficiency in relation to prior art thin film solar cell devices.

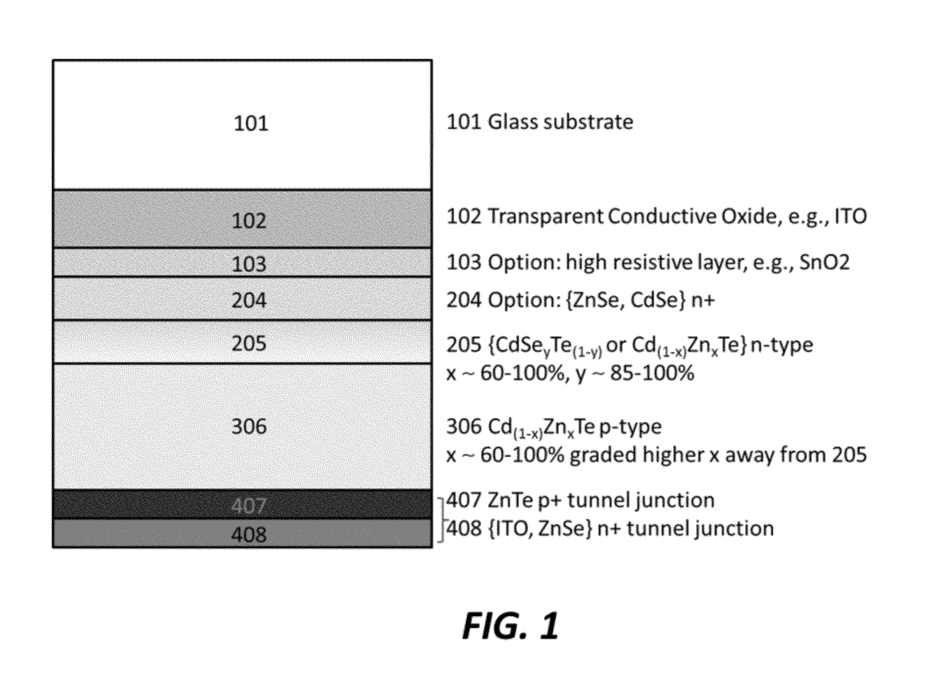

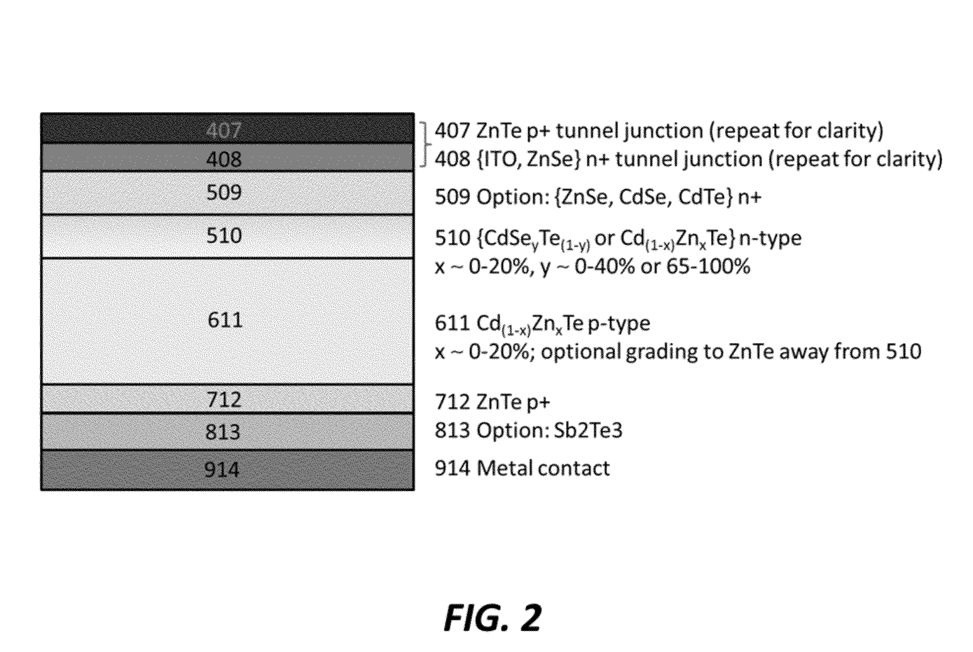

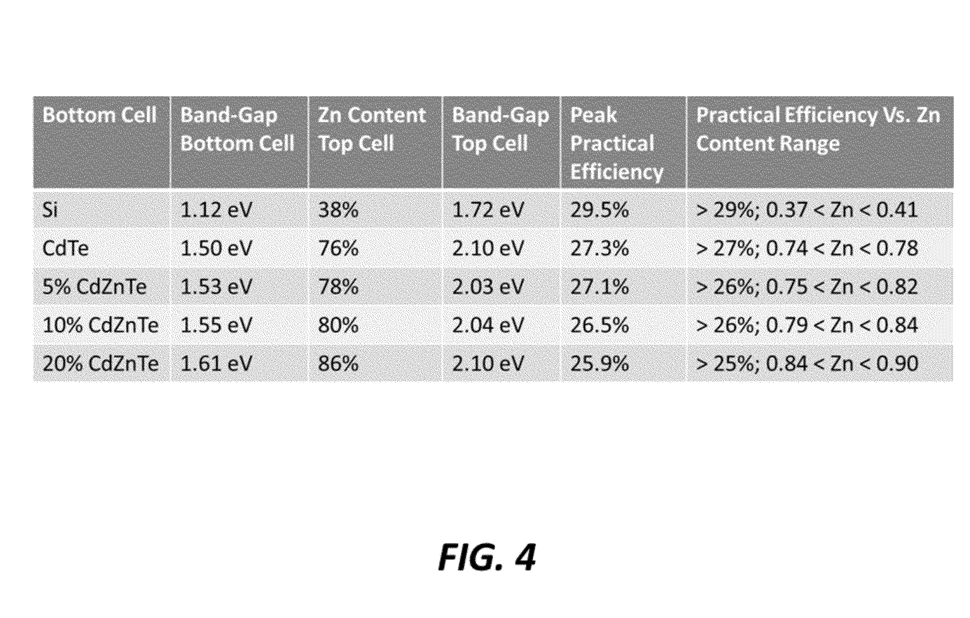

Methods and structures of the present disclosure can provide photovoltaic devices with improved short circuit current (Jsc), open circuit voltage (Voc), and fill factor (FF) in relation to prior art thin film photovoltaic devices. Examples of practical efficiencies for suitably tuned top and bottom solar cells, such as those of FIGS. 1 and 2, are shown in FIG. 4. Photovoltaic devices having practical, realizable power efficiencies in excess of 25% are achievable.

Thin film solar cell structures of the present disclosure can be formed in one or more in-line vacuum chambers configured for molecular effusion deposition (MED). The one or more vacuum chambers may include a primary molecular effusion source chamber and one or more in-line auxiliary (or secondary) chambers. The vacuum chambers can be maintained under medium vacuum (1×10⁻⁶ to 1×10⁻⁴ Torr) or high vacuum (1×10⁻⁸ to 1×10⁻⁷ Torr) during operation with the aid of a pumping system comprising one or more of an ion pump, a turbomolecular (“turbo”) pump, a cryopump and a diffusion pump. The pumping system may also include one or more “backing” pumps, such as mechanical or dry scroll pumps. Vacuum chambers of the present disclosure may include a main deposition chamber for forming various device structures, in addition to auxiliary chambers for forming additional device structures, such as, e.g., backside metal contact (“metallization”), transparent conductive oxides, thermal annealing under suitable material over pressures, and laser cell scribing. In an alternative embodiment, multiple in-line vacuum chambers can be arranged to provide particular layer depositions of the overall device structure, with increases in overall through-put. Molecular source systems of the present disclosure may comprise one or more vacuum chambers, pumping systems and a computer system configured to control vacuum chamber pressure, substrate temperature, material source temperatures, and various parameters (e.g., source partial pressure, source flux, deposition time, exposure time) associated with the deposition of solar cell device structures.

This deposition method applies to any vacuum deposition technique that can (i) control the doping as the material is grown (in situ), (ii) control the thicknesses of different compositional layers, (iii) control the deposition rate during growth, and (iv) control the compositional change from one layer to another layer by varying the ratio of elements in the composition. This includes, but is not limited to, conventional (solid phase) MBE, gas phase MBE (GPMBE), and metalorganic chemical vapor deposition (MOCVD), and any other vapor deposition that meets the above requirements, especially requirements (i)-(iii). In a preferable embodiment, the MED approach is employed.

In embodiments of the invention, methods, apparatuses and/or structures provide for the following: (i) poly-crystalline growth at high deposition rates and low temperatures; (ii) cell architectures with energy band-gaps in the range between approximately 1.1 eV and 2.1 eV (iii) deposition with complete doping control, in situ, to optimize the cell structure with respect to doping concentrations; (iv) compositional grading of heterojunction layers to optimize the cell structure by significant reduction in interface recombination sites; (v) the capability to heavily dope material grown over a superstrate (or substrate), in situ, near front and back contacts to create one or more low ohmic contacts; (vi) providing passivation of grain boundaries, in situ, by doping or pinning or compensating the grain boundaries to repel minority carriers from the boundary recombination sites; and (vii) providing complete deposition rate control to allow deposition interruption for crystallizing anneals, in situ, and allowing highly reduced growth rate for the initial seed layers in order to optimize grain size. In embodiments, capabilities (iii) and (iv) above, when combined, allow for complete control over the position of the junction for the heterostructure for optimized performance.

As used herein, “n-type layer” refers to a layer having an n-type chemical dopant (intrinsic or extrinsic) and “p-type layer” refers to a layer having a p-type chemical dopant (intrinsic or extrinsic). N-type layers and p-type layers can have other materials in addition to n-type and p-type dopants. For example, an n-type CdTe layer is a layer formed of Cd and Te that is also chemically doped n-type. As another example, a p-type ZnTe layer is a layer having Zn and Te that is also chemically doped p-type.

In an aspect of the invention, a dual n-p junction (“tandem”) solar cell device is deposited by an MED technique on a glass superstrate with a transparent conductive oxide (TCO) and optional thin, high resistance transparent (HRT) layer. In a preferable embodiment, a highly doped n-type front layer of the structure serves as the low ohmic contact to the TCO layer. The successive semiconductor layers deposited provide, in sequence: an optional thin high doped n-type, low ohmic contact layer to the TCO, a first n-p poly-crystalline, near lattice-matched hetero- or homo-junction, a thin high doped p-type contact layer that can also serves as the first layer of a p+/n+ tunnel junction, an n+ second layer of a p+/n+ tunnel junction, an optional high doped n-type contact layer to the n+ side of the tunnel junction, a second n-p poly-crystalline, near lattice-matched hetero- or homo-junction, an optional low ohmic “semimetal” contact, and a final metal contact at the backside of the structure.

In another aspect of the invention the two poly-crystalline, near lattice-matched hetero- or homo-junction solar cells are CdTe-based alloys with band-gaps tuned by compositional variation to provide an optimal absorption of the solar spectrum to maximize the power conversion efficiency. Each n-p junction layer can be compositionally graded as the layer moves away from the metallurgical junction in order to optimize band-gap alignment and/or doping at the side in contact with the high doped contact layers.

In some embodiments, the solar cell structure may have at least 4 layers of different compound semiconductor materials. In some instances those semiconductor materials may comprise, ZnTe, ZnSe, CdSe, MgTe, MgSe, x-graded Cd₍₁₋ₓ₎ZnₓTe, CdSeₓTe₍₁₋ₓ₎, MgSeₓTe₍₁₋ₓ₎, and CdTe. The solar cell structure may optionally include a SbₘTeₙ layer over the p+ ZnTe electrical contact layer to enhance the low ohmic contact to the back metal contact.

With reference to FIGS. 1 and 2, a tandem poly-crystalline photovoltaic (“PV”) CdTe-alloy based solar cell structure comprises a glass superstrate with a transparent conductive oxide, such as indium oxide, indium tin oxide (ITO), fluorine tin oxide or zinc oxide, an optional high resistance transparent (HRT) layer over the TCO, a first solar cell (“top” cell) that receives the incident solar light and comprises an optional high doped n-type ZnSe or CdSe layer over the HRT, an n-type CdSeTe or CdZnTe emitter layer over the ZnSe or CdSe layer, a near or perfect lattice-matched p-type CdZnTe absorber layer adjacent to the CdSeTe or CdZnTe emitter layer, and a final p+ ZnTe layer that forms the p-layer of a tunnel junction connecting the first (“top”) and second (“bottom”) solar cells. The n-type CdSeTe or CdZnTe and p-type CdZnTe adjacent layers define the top cell n-p hetero- or homo-junction with composition selected to optimize both the band structure alignment and lattice-matching with respect to power conversion efficiency. In an embodiment, the Cd₍₁₋ₓ₎ZnₓTe absorber and emitter layers have ‘x’ between about 0.5 and 0.95, or 0.70 and 0.90, or between 0.75 and 0.80, and the CdSe_{y}Te_{(1-y)} emitter layer has ‘y’ between about 0.5 and 1.0, or 0.7 and 1.0, or 0.85 and 1.0.

With continued reference to FIGS. 1 and 2, a second solar cell (the “bottom” cell), that receives the solar light transmitted through the top cell, is electrically connected to the top cell through the p+/n+ tunnel junction. In some embodiments, the p+ layer of the tunnel junction comprises the final p+ ZnTe layer of the top cell and the n+ layer comprises either a transparent conductive oxide such as ITO or a near transparent n+ ZnSe or n+ CdSe window layer that also forms the n+ first layer of the bottom cell. The bottom cell comprises in sequence an optional high doped n-type ZnSe or CdSe layer, an n-type CdSeTe or CdZnTe emitter layer, a p-type CdZnTe absorber layer, a p+ ZnTe contact layer, an optional SbₘTeₙ semi-metal layer, and a final Mo metal contact. The n-type CdSeTe or CdZnTe and p-type CdZnTe adjacent layers define the bottom cell n-p hetero- or homo-junction with composition selected to optimize both the band structure alignment and lattice-matching with respect to power conversion efficiency. In an embodiment, the Cd₍₁₋ₓ₎ZnₓTe absorber and emitter layers have ‘x’ between about 0 and 0.20, or 0.05 and 0.10, and the CdSe_{y}Te_{(1-y)} emitter layer has ‘y’ between about 0 and 0.40, or 0.10 and 0.30, or between about 0.70 and about 0.85, in some cases for optimal lattice-matching and band alignment.

In FIG. 1, the top cell of a dual junction poly-crystalline/poly-crystalline photovoltaic (or solar) cell includes, from top to bottom, a glass substrate 101, a transparent conductive oxide layer 102 (e.g., ITO), a high resistive layer 103 (e.g., SnO₂), an n+ layer 204, (e.g., ZnSe, CdSe), an n-type emitter 205 (e.g., CdSe_{y}Te_{(1-y)}, Cd₍₁₋ₓ₎ZnₓTe), a p-type absorber 306 (e.g., Cd₍₁₋ₓ₎ZnₓTe), a p+ tunnel junction 407 (e.g., ZnTe), and an n+ tunnel junction 408 (ITO or ZnSe). In some cases, layers 103 and/or 204 are precluded. In FIG. 2, the bottom cell (adjacent to the top cell) includes the p+ tunnel junction 407, the n+ tunnel junction 408, an n+ layer 509 (e.g., ZnSe, CdSe, CdTe), an n-type emitter 510 (e.g., CdSe_{y}Te_{(1-y)}), a p-type absorber 611 (e.g., Cd₍₁₋ₓ₎ZnₓTe), a p+ layer 712 (e.g., ZnTe), a semi-metal layer 813 (e.g., Sb₂Te₃) and a metal contact 914. In some cases, layers 509 and/or 813 are precluded. As an alternative to FIGS. 1 and 2, the doping configuration in the solar cell layers can be reversed such that, for example, the top solar cell layers 204, 205, and 306 from the top are in the sequence 306, 205, and 204 from the top; the bottom solar cell layers 509, 510, 611, and 712 from the top are in the sequence 712, 611, 510, and 509 from the top; the tunnel junction layers 407 and 408 from the top are in the sequence 408 and 407. In some embodiments, the top cell n-p junction layers and the bottom cell n-p junction layers can be compositionally graded as the layers move away from the metallurgical junction in order to optimize band-gap alignment and/or doping at the side in contact with the high doped contact layers.

The layers can be deposited by MED at a deposition rate between about 6 micrometer (microns) and 12 microns per hour, or between about 15 microns and 30 microns per hour. The layers are deposited at a substrate temperature between about 150° C. and 350° C. or between about 200° C. and 300° C. The MED contact layers are deposited at a thickness between about 20 nanometers (nm) and 150 nm, or between 50 nm and 100 nm. The MED emitter layers are deposited at a thickness between about 200 nm and 500 nm and the absorber layers are deposited at a thickness between about 1 microns and 4 microns or between about 1.5 microns and 2.5 microns.

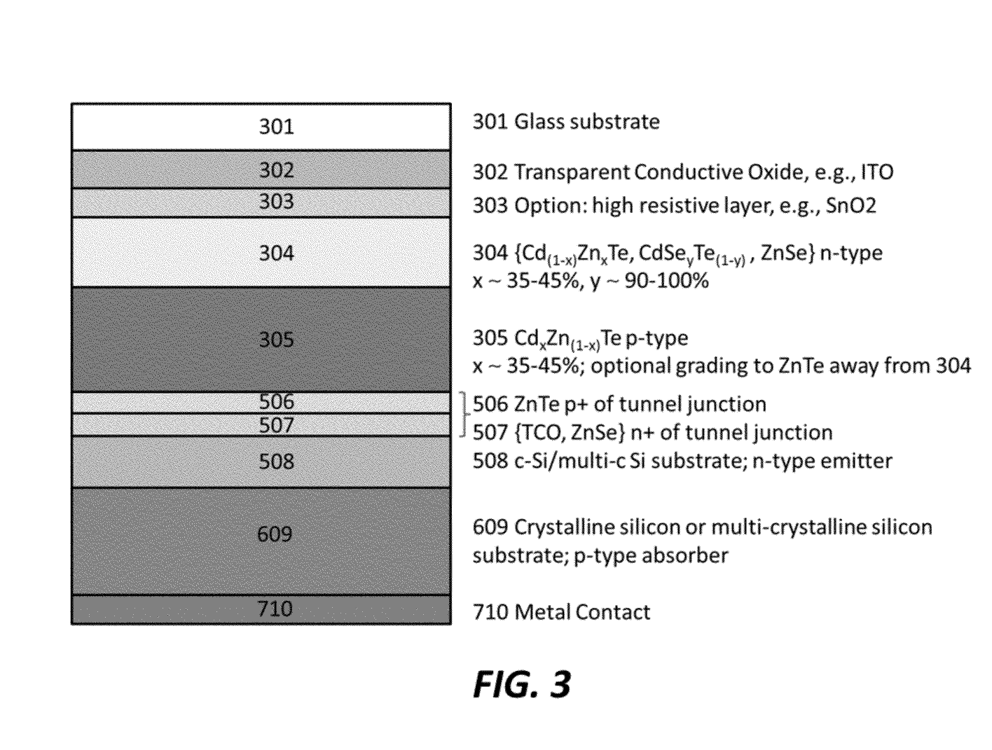

With reference to FIG. 3, another tandem solar cell comprises a poly-crystalline PV CdTe-alloy based top solar cell deposited onto a p-type (n-type) silicon substrate with embedded n-type (p-type) emitter on the deposition side of the substrate. The silicon structure comprises in sequence from the backside of the silicon substrate, a metal contact, an optional high doped p+ (n+) silicon layer in contact with the metal contact, a p-type (n-type) absorber layer that is the bulk of the silicon substrate and an n-type (p-type) emitter layer. The p-n layers form the fixed band-gap silicon homo-junction bottom solar cell that receives light transmitted through the top cell.

With continued reference to FIG. 3, a second solar cell (the “top” cell), that receives the incident solar light, is electrically connected to the bottom silicon cell through the n+/p+ (p+/n+) tunnel junction. In some embodiments, the n+ layer of the tunnel junction comprises either a transparent conductive oxide such as ITO or n+ ZnSe, and/or the n+ silicon emitter layer itself; the p+ layer of the tunnel junction comprises p+ ZnTe and/or the p+ silicon emitter layer (for the inverted case). The top cell comprises in sequence a p-type CdZnTe absorber layer over the p+ ZnTe tunnel junction layer, an n-type CdZnTe or CdSe emitter layer, or ZnSe emitter/window layer, an optional HRT layer, and a final TCO contact layer. The p-type CdZnTe and n-type CdSe (ZnSe) or CdZnTe adjacent layers define the top cell p-n hetero- or homo-junction, with composition selected to optimize both the band structure alignment and lattice-matching with respect to power conversion efficiency. In an embodiment, the Cd₍₁₋ₓ₎ZnₓTe absorber/emitter layers have ‘x’ between about 0.30 and 0.50, or between 0.35 and 0.45 for optimal band-gap and lattice-matching.

In FIG. 3, the dual junction Group II-VI poly-crystalline CdZnTe/crystalline silicon photovoltaic (solar) cell includes, from top to bottom, a glass substrate 301, a transparent conductive oxide layer 302 (e.g., ITO), a high resistive layer 303 (e.g., SnO₂), an n-type emitter 304 (e.g., Cd₍₁₋ₓ₎ZnxTe, CdSe, ZnSe), a p-type absorber 305 (e.g., CdₓZn₍₁₋ₓTe), a p+ tunnel junction 506 (e.g., ZnTe), an n+ tunnel junction 507 (ITO, ZnSe), an n-type emitter 508 (e.g., crystalline or multi-crystalline silicon), a p-type absorber 609 (e.g., crystalline or multi-crystalline silicon) and a metal contact 710. In some cases, layer 303 is precluded. As an alternative to FIG. 3, the solar cell layers can be reversed such that, for example, top solar cell layers 304 and 305 from the top are in the sequence 305 and 304 from the top; the bottom solar cell layers 508 and 609 from the top are in the sequence 609 and 508 from the top; the tunnel junction layers 506 and 507 from the top are in the sequence 507 and 506.

In some embodiments, the top cell n-p junction layers can be compositionally graded as the layers move away from the metallurgical junction in order to optimize band-gap alignment and/or doping at the side in contact with the high doped contact layers.

The top cell layers can be deposited by MED at a deposition rate between about 6 microns and 12 microns per hour, or between about 15 microns and 30 microns per hour. The layers are deposited at a substrate temperature between about 150° C. and 350° C. or between about 200° C. and 300° C. The MED contact layers are deposited at a thickness between about 20 nm and 150 nm, or between 50 and 100 nm. The MED emitter layers are deposited at a thickness between about 200 nm and 500 nm and the absorber layers are deposited at a thickness between about 1 and 4 microns or between about 1.5 microns and 2.5 microns.

Methods and devices of the present disclosure may be combined with or modified by other methods or devices, such as those described in U.S. patent application Ser. No. 12/999,048, U.S. patent application Ser. No. 12/965,800, U.S. Pat. No. 8,298,856, U.S. Pat. No. 8,580,602, U.S. Pat. No. 8,664,524, and U.S. Pat. No. 8,828,783, which are entirely incorporated herein by reference for all purposes.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

1-15. (canceled)

16. A photovoltaic device, comprising:
(a) a glass substrate;
(b) a first n-type emitter adjacent to said glass substrate, said first n-type emitter comprising two or more of cadmium (Cd), tellurium (Te), selenium (Se) and zinc (Zn);
(c) a first p-type absorber adjacent to said first n-type emitter, said first p-type absorber comprising Cd, Zn and Te;
(d) a second n-type emitter adjacent to said first p-type absorber, said second n-type emitter comprising silicon; and
(e) a second p-type absorber adjacent to said second n-type emitter, said second p-type absorber comprising silicon.

17. The photovoltaic device of claim 16, wherein said second n-type emitter comprises crystalline or multi-crystalline silicon.

18. The photovoltaic device of claim 16, wherein said second p-type absorber comprises crystalline or multi-crystalline silicon.

19. The photovoltaic device of claim 16, further comprising a p-n tunnel junction between said first p-type absorber and said second n-type emitter.

20. The photovoltaic device of claim 16, wherein said first n-type emitter comprises Cd, Zn and Te.

21. The photovoltaic device of claim 20, wherein said first n-type emitter is compositionally graded in Cd and Zn.

22. The photovoltaic device of claim 16, wherein said first n-type emitter comprises two or more of Cd, Te and Se.

23. The photovoltaic device of claim 22, wherein said first n-type emitter comprises Cd and Se.

24. The photovoltaic device of claim 16, wherein said first p-type absorber is compositionally graded in Cd and Zn.

25. The photovoltaic device of claim 16, further comprising a transparent conductive oxide layer between said glass substrate and said first n-type emitter.

26. The photovoltaic device of claim 25, wherein said transparent conductive oxide layer comprises indium tin oxide.

27. The photovoltaic device of claim 25, further comprising a high resistive layer comprising tin (Sn) and oxygen (O) between said TCO and said first n-type emitter.

28. The photovoltaic device of claim 19, wherein said p-n tunnel junction comprises a p-type layer adjacent to an n-type layer, wherein said p-type layer comprises Te and Zn, and wherein said n-type layer comprises (i) Zn and Se or (ii) indium tin oxide.

29-54. (canceled)
